(19) United States
(12) Patent Application Publication
(10) Pub. No.: US 2013/0341657 A1
(43) Pub. Date: Dec. 26, 2013

(54) LIGHT-EMITTING MODULE AND LUMINAIRE

(71) Applicant: Tsuyoshi OYAIZU, Kanagawa (JP)

(72) Inventor: Tsuyoshi OYAIZU, Kanagawa (JP)

(73) Assignee: Toshiba Lighting & Technology Corporation, Kanagawa (JP)

(21) Appl. No.: 13/612,464

(22) Filed: Sep. 12, 2012

(30) Foreign Application Priority Data
Jun. 26, 2012 (JP) 2012-143333

(51) Int. Cl. H01L 33/08

(52) U.S. Cl. 257/89; 257/E33.055

(57) ABSTRACT

A light-emitting module includes a substrate in an embodiment. The light-emitting module includes a first light-emitting element mounted on the substrate through a first connecting structure in an embodiment. The light-emitting module includes a second light-emitting element having a light-emitting efficiency that is more sensitive to a change in temperature than that of the first light-emitting element, and mounted on the substrate through a second connecting structure having a higher thermal radiation than the first connecting structure.

### CROSS-REFERENCE TO RELATED APPLICATION

This application is based upon and claims the benefit of priority from the prior Japanese Patent Application No. 2012-143333 filed on Jun. 26, 2012; the entire contents of which are incorporated herein by reference.

### FIELD

Embodiments described herein relate generally to a light-emitting module and a luminaire.

### BACKGROUND

In recent years, a luminaire having an energy efficient light-emitting element such as an LED (Light Emitting Diode) is used as a luminaire. The luminaire having the light-emitting element provides higher brightness or illuminance with smaller power consumption in comparison with an incandescent lamp of the related art.

The luminaire having the light-emitting element may be provided with a plurality of types of the light-emitting elements having different light-emitting colors mounted on a light-emitting module. In this case, light output from the luminaire is a mixture of a plurality of light beams output from the respective plurality of types of light-emitting elements mounted on the light-emitting module. In other words, a light-emitting color output from the luminaire is a mixture of light-emitting colors from the respective types of the light-emitting elements.

### DESCRIPTION OF THE DRAWINGS

FIG. 1 illustrates a vertical cross-sectional view of a luminaire having a light-emitting module according to a first embodiment mounted thereon;

FIG. 2 illustrates a top view of the light-emitting module according to the first embodiment;

FIG. 3 illustrates a lateral cross-sectional view of the luminaire having the light-emitting module according to the first embodiment mounted thereon;

FIG. 4 illustrates electric wiring of the light-emitting module according to the first embodiment;

FIG. 5 illustrates reflection of light-emitting colors of the respective light-emitting elements in the light-emitting module according to the first embodiment;

FIG. 6 illustrates an example of a structure of the light-emitting module showing a case where the light-emitting elements having two electrodes on the lower surface thereof are connected to a substrate;

FIG. 7 illustrates an example of a structure of the light-emitting module showing a case where the light-emitting elements each having one electrode connected to another with a bonding wire on an upper surface thereof and one electrode on the lower surface thereof are connected to the substrate;

FIG. 8 illustrates an example of a structure of the light-emitting module showing a case where the light-emitting elements each having two electrodes connected to others with the bonding wires on an upper surface thereof are connected to the substrate;

FIG. 9 illustrates an example of a circuit diagram in a case where a red LED and a blue LED are connected in series;

FIG. 10 illustrates a top view of the light-emitting module according to a second embodiment; and

FIG. 11 illustrates a top view of the light-emitting module according to a third embodiment.

### DETAILED DESCRIPTION

According to one embodiment, a light-emitting module includes a substrate, a first light-emitting element, and a second light-emitting element. The first light-emitting element is mounted on the substrate through a first connecting structure. The second light-emitting element has a light-emitting efficiency that is more sensitive to a change in temperature than that of the first light-emitting element. The second light-emitting element is mounted on the substrate through a second connecting structure having a higher thermal radiation than the first connecting structure.

Hereinafter, various embodiments will be described with reference to the accompanying drawings.

A light-emitting module according to embodiments includes a substrate and a first light-emitting element which is mounted on the substrate through a first connecting structure. The light-emitting module includes a second light-emitting element. The second light-emitting element has a light-emitting efficiency that is more sensitive to a change in temperature than that of the first light-emitting element. The second light-emitting element is mounted on the substrate through a second connecting structure having a higher thermal radiation than the first connecting structure.

In the light-emitting module according to the embodiments, a thermal resistance between the second light-emitting element and the substrate is lower than a thermal resistance between the first light-emitting element and the substrate

In the light-emitting module according to the embodiments, the light-emitting efficiencies of the first light-emitting element and the second light-emitting element decrease in response to an increase in temperature, and increase in response to a decrease in temperature.

In the light-emitting module according to the embodiments, for example, the first light-emitting element is a blue LED (Light Emitting Diode) element and the second light-emitting element is a red LED element.

In the light-emitting module according to the embodiments, for example, the light-emitting element and the substrate are connected through a first die-bonding agent in the first connecting structure. Also, for example, in the second connecting structure, the light-emitting element and the substrate are connected through a second die-bonding agent having a lower thermal resistance than the first die-bonding agent.

In the light-emitting module according to the embodiments, for example, the first light-emitting element and the second light-emitting element each include two electrodes on an upper surface thereof. The first light-emitting element and the substrate are connected through a silicone agent. The second light-emitting element and the substrate are connected through a silver paste.

In the light-emitting module according to the embodiments, for example, The substrate includes a wiring pattern on a surface thereof. The first light-emitting element includes two electrodes on an upper surface thereof, the second light-emitting element includes at least one electrode on a lower surface thereof. The first light-emitting element and the substrate are connected through a silicone agent. The electrode of the second light-emitting element and the wiring pattern of the substrate are in direct contact with each other.

In the embodiments given below, description will be given using a case where the light-emitting element is an LED (Light Emitting Diode). However, the light-emitting element is not limited thereto. For example, the light-emitting element may be an organic EL (OLED: (Organic Light Emitting Diode)) or may be other light-emitting elements which emit light of a predetermined color by supplying an electric current, such as a semiconductor laser.

In the embodiments given below, description will be given using an example in which the first light-emitting element is the blue LED (Light Emitting Diode) element and the second light-emitting element is the red LED element. However, the light-emitting element is not limited thereto. In other words, the second light-emitting element may be any suitable light-emitting element as long as it is a light-emitting element having a ratio of change of light-emitting efficiency with respect to a change in temperature is larger than that of the first light-emitting element. For example, both of the first light-emitting element and the second light-emitting element may be light-emitting elements which emit light in blue, and may be any other suitable light-emitting elements.

In the embodiments described below, the LED is formed of a light-emitting diode chip including a gallium-nitride (GaN)-based semiconductor emitting blue light and a four raw materials (Al, In, Ga, P) compound-based semiconductor emitting red light. Part or all of a plurality of the LEDs are mounted in a regularly arranged manner at a certain distance such as a matrix pattern, a zigzag pattern, or a radial pattern using, for example, COB (Chip On Board) technique. The LED may be configured in a form of an SMD (Surface Mount Device) type. In the embodiments described below, the plurality of LEDs constitute an LED group including any suitable number of the same type of the LEDs that various changes in design may be made according to applications of illumination.

In the embodiments described below, the luminaire is described as having a krypton bulb shape. However, the shape of the luminaire is not limited thereto, and may be of a general bulb shape and a bombshell shape.

### First Embodiment

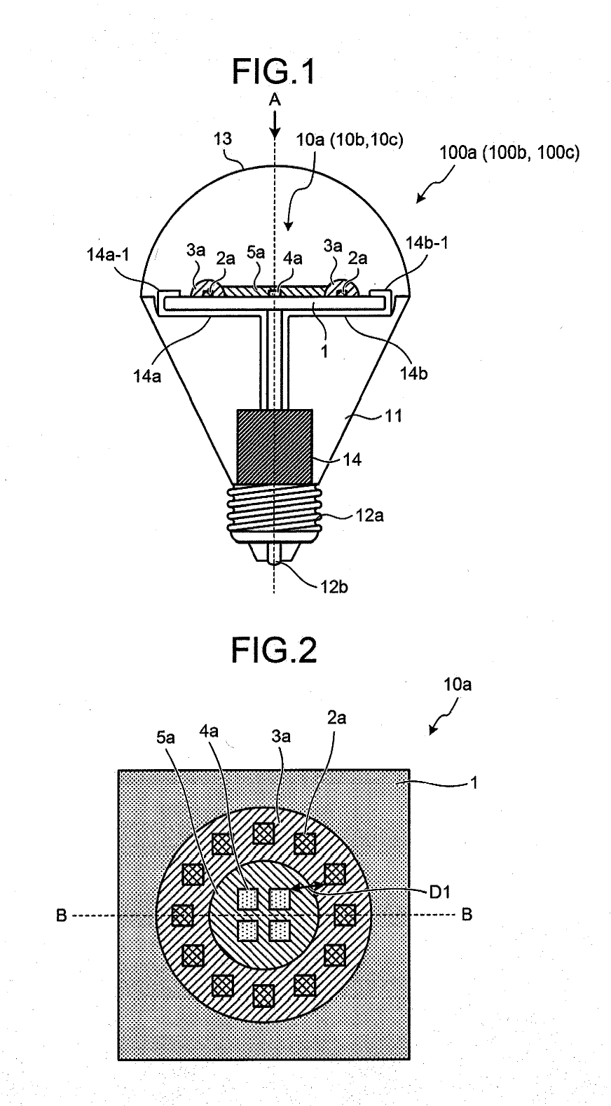

FIG. 1 illustrates a vertical cross-sectional view of a luminaire having a light-emitting module according to a first embodiment mounted thereon. As illustrated in FIG. 1, a luminaire 100a according to the first embodiment includes a light-emitting module 10a. Also, the luminaire 100a includes a main body 11, a cap member 12a, an eyelet portion 12b, a cover 13, a control unit 14, electric wiring 14a, an electrode bonding portion 14a-1, electric wiring 14b, and an electric bonding portion 14b-1.

The light-emitting module 10a is arranged on an upper surface of the main body 11 in the perpendicular direction. The light-emitting module 10a includes a substrate 1. The substrate 1 is formed of ceramics of a low rate of thermal transfer, for example, alumina. The rate of thermal transfer of the substrate 1 is, for example, 33 [W/m·K] under 300 [K] atmosphere.

If the substrate 1 is formed of ceramics, mechanical strength and dimensional accuracy are also high, and hence contributes to improvement of yield, reduction of manufacturing cost of the light-emitting module 10a, and achievement of long service life of the light-emitting module 10a when the light-emitting module 10a is mass-produced. Also, the ceramics improves the light-emitting efficiency of the LED module since the reflection ratio of visible light is high.

The material of the substrate 1 is not limited to alumina, but may be silicon nitride or silicon oxide. The rate of thermal transfer of the substrate 1 is preferably 20 to 70 [W/m·K]. If the rate of thermal transfer of the substrate 1 is 20 to 70 [W/m·K], the manufacturing cost, reflectance, and thermal effects among the light-emitting elements mounted on the substrate 1 may be inhibited. Also, the substrate 1 formed of ceramics having suitable rate of thermal transfer is capable of inhibiting the thermal effects among the light-emitting elements mounted on the substrate 1 in comparison with those having a high rate of thermal transfer. Therefore, the substrate 1 formed of ceramics having a suitable rate of thermal transfer allows a separation distance among the light-emitting elements mounted on the substrate 1 to be reduced, so that further downsizing is enabled.

The substrate 1 may be formed of nitride of aluminum such as aluminum nitride. In this case, the rate of thermal transfer of the substrate 1 is smaller than 225 [W/m·K] which is the rate of thermal transfer of aluminum having approximately 99.5 mass %, for example, under 300[K] atmosphere.

The light-emitting module 10a includes first light-emitting elements 2a arranged on a circumference of an upper surface of the substrate 1 in the perpendicular direction. The light-emitting module 10a may include, for example, second light-emitting elements 4a arranged near the center of the upper surface of the substrate 1 in the perpendicular direction. The light-emitting amount of the second light-emitting elements 4a is further decreased with increase in temperature of the light-emitting elements in comparison with the first light-emitting elements 2a. In other words, the second light-emitting elements 4a has an inferior thermal property in comparison with the first light-emitting elements 2a in that the light-emitting amount of the light-emitting element is further decreased with increase in temperature of the light-emitting elements. According to the first embodiment, forming the substrate 1 of ceramics having a lower rate of thermal transfer prevents heat generated by the first light-emitting elements 2a from being transferred to the second light-emitting elements 4a via the substrate 1, and deterioration of the light-emitting efficiency of the second light-emitting elements 4a is inhibited.

In FIG. 1, the first light-emitting elements 2a and the second light-emitting elements 4a are illustrated with decreased numbers. In other words, as a first light-emitting element group, a plurality of the first light-emitting elements 2a are arranged on the circumference of the upper surface of the substrate 1 in the perpendicular direction. As a second light-emitting element group, a plurality of the second light-emitting elements 4a are arranged in the vicinity of the center of the upper surface of the substrate 1 in the perpendicular direction.

The first light-emitting element group including the plurality of first light-emitting elements 2a is covered with a sealing member 3a from above. The sealing member 3a has a substantially semicircular or substantially trapezoidal shape in cross section on an upper surface of the substrate 1 in the perpendicular direction, and is formed into a circular ring shape so as to cover the plurality of first light-emitting elements 2a. Also, the second light-emitting element group including the plurality of second light-emitting elements 4a is covered with a sealing member 5a from above together with a depression formed by an inner surface of the circular ring formed by the sealing member 3a and the substrate 1.

The sealing member 3a and the sealing member 5a may be formed of various resins such as epoxy resin, urea resin, and silicone resin as members. The sealing member 5a may be a transparent resin containing no phosphor and having a high diffusing property. The sealing member 3a and the sealing member 5a are formed of different types of the resins. Then, an index of refraction n1 of light of the sealing member 3a, an index of refraction n2 of light of the sealing member 5a, and an index of refraction n3 of light of gas enclosed in a space formed by the main body 11 and the cover 13 have a magnitude relationship of, for example, n3<n1<n2. Hereinafter, gas to be enclosed in the space formed by the main body 11 and the cover 13 is referred to as “enclosed gas”. The enclosed gas is, for example, atmospheric air.

In the light-emitting module 10a, an electrode 6a-1 described later is connected to the electrode bonding portion 14a-1. In the light-emitting module 10a, an electrode 8a-1 described later is connected to the electrode bonding portion 14b-1.

The main body 11 is formed of a metal having a good rate of thermal transfer, for example, aluminum. The main body 11 is formed into a column shape having a substantially circular lateral cross section, and the cover 13 is attached to one end and the cap member 12a is attached to the other end. The main body 11 is formed so as to form a substantially conical-shaped tapered surface having a diameter gradually reducing from one end to the other end. The main body 11 is formed to have a shape analogous to a silhouette of a neck portion of a mini krypton bulb in appearance. The main body 11 includes a number of thermal radiation fins, not shown, projecting radially from one end to the other end formed integrally with an outer peripheral surface.

The cap member 12a is provided with, for example, an Edison type E-type cap, and includes a cylindrical shell formed of a copper plate and provided with a thread and the electrically conductive eyelet portion 12b provided on a crowning at a lower end of the shell via an electrically insulating portion. An opening of the shell is fixed to an opening of the main body 11 at the other end so as to be electrically insulated. An input line, not shown, drawn from an electric input terminal of a circuit substrate, not shown, of the control unit 14 is connected to the shell and the eyelet portion 12b.

The cover 13 forms a globe and is formed, for example, into a smooth curved shape analogous to the silhouette of the mini krypton bulb having an opening at one end with milky white polycarbonate. The cover 13 is fixed by an opening end portion thereof fitted to the main body 11 so as to cover a light-emitting surface of the light-emitting module 10a. Accordingly, the luminaire 100a is analogous to the silhouette of the mini krypton bulb in general appearance shape provided with the globe as the cover 13 at one end and the E-type cap member 12a at the other end, and is configured as a capped lamp which can be replaced with the mini krypton bulb. A method of fixing the cover 13 to the main body 11 may be any suitable method such as bonding, fitting, screwing, or engaging.

The control unit 14 accommodates a lighting circuit, not shown, which controls lighting of the first light-emitting elements 2a and the second light-emitting elements 4a mounted on the substrate 1 so as to be electrically insulated from the outside. The control unit 14 converts AC voltage to DC voltage, and supplies the converted DC voltage to the first light-emitting elements 2a and the second light-emitting elements 4a. The control unit 14 includes the electric wiring 14a for distributing electricity to the first light-emitting elements 2a and the second light-emitting elements 4a connected to an output terminal of the lighting circuit thereof. The control unit 14 also includes second electric wiring 14b connected to an input terminal of the lighting circuit thereof. The electric wiring 14a and the electric wiring 14b are covered so as to be insulated.

Here, the lighting circuit supplies electricity to light-emitting modules 10a to 10c. The first light-emitting element group and the second light-emitting element group connected to the light-emitting module 10a to 10c are connected to the lighting circuit via a common electricity supplying route. However, the first light-emitting element group and the second light-emitting element group are not limited thereto, and may be connected to the lighting circuit via a different electricity supplying route, or may be connected to a different lighting circuit.

The electric wiring 14a is drawn out to an opening of the main body 11 at one end via a through hole, not shown, or a guide groove, not shown formed on the main body 11. The electric wiring 14a is joined at the electrode bonding portion 14a-1 which is a distal end portion having an insulating coating peeled off to the electrode 6a-1 of the wiring arranged on the substrate 1. The electrode 6a-1 will be described later.

The electric wiring 14b is drawn out to the opening of the main body 11 at one end via the through hole, not shown or a guide groove, not shown formed on the main body 11. The electric wiring 14b is joined at the electrode bonding portion 14b-1 which is the distal end portion having the insulating coating peeled off to the electrode 8a-1 of the wiring arranged on the substrate 1. The electrode 8a-1 will be described later.

In this manner, the control unit 14 supplies electricity input via the shell and the eyelet portion 12b to the first light-emitting elements 2a and the second light-emitting elements 4a via the electric wirings 14a. Then, the control unit 14 collects electricity supplied to the first light-emitting elements 2a and the second light-emitting elements 4a via the electric wirings 14b.

FIG. 2 illustrates a top view of the light-emitting module according to the first embodiment. FIG. 2 illustrates a top view of the light-emitting module 10a viewed from a direction indicated by an arrow A in FIG. 1. As illustrated in FIG. 2, the first light-emitting element group including the plurality of first light-emitting elements 2a is arranged regularly in a circular ring shape on a circumference of the center of the substantially rectangular-shaped substrate 1. The first light-emitting element group including the plurality of first light-emitting elements 2a is covered entirely in a circular ring shape with the sealing member 3a. In the substrate 1, an area covered with the sealing member 3a is referred to as a first area.

As illustrated in FIG. 2, the second light-emitting element group including the plurality of second light-emitting elements 4a is arranged regularly in a reticular pattern near the center of the substantially rectangular-shaped substrate 1. The LED group including the plurality of second light-emitting elements 4a is covered entirely with the sealing member 5a. The sealing member 5a covers the interior of the circular ring of the first area described above entirely. In the substrate 1, an area covered with the sealing member 5a is referred to as a second area.

A detailed example of wiring of the first light-emitting elements 2a and the second light-emitting elements 4a, and a detailed connecting structure which connects the first light-emitting elements 2a and the second light-emitting elements 4a to the substrate 1 will be described later and will not be described here.

As illustrated in FIG. 2, the shortest distance among the distances between the first light-emitting elements 2a and the second light-emitting elements 4a is defined as a distance D1 between the first light-emitting element 2a and the second light-emitting element 4a. The distance between the first light-emitting element 2a and the second light-emitting element 4a is not limited to the shortest distance among the distances between the first light-emitting elements 2a and the second light-emitting elements 4a, but may be a distance between a center position of the first light-emitting element group and a center position of the second light-emitting element group. In the example illustrated in FIG. 2, for example, the center position of the first light-emitting element group is a circumference which passes respective centers of the first light-emitting elements 2a arranged in a circular ring shape. For example, the center position of the second light-emitting element group corresponds to a center of an area where the second light-emitting elements 4a are arranged in the reticular pattern. In this case, the distance between the first light-emitting elements 2a and the second light-emitting elements 4a is a distance between the center of the area where the second light-emitting elements 4a are arranged in the reticular pattern and a point on the circumference passing through the respective centers of the first light-emitting elements 2a arranged into the circular ring shape.

The light-emitting module 10a is capable of inhibiting effects of heat generated by the first light-emitting elements 2a on the second light-emitting elements 4a even if a plurality of types of LEDs having thermal properties significantly different from each other are consolidated in separate areas by the type of the LED on the substrate 1 formed of ceramics. Therefore, the light-emitting module 10a can easily have desired light-emitting properties.

The light-emitting module 10a includes, for example, the first light-emitting elements 2a and the second light-emitting elements 4a in separate areas. Therefore, since the light-emitting module 10a inhibits, for example, the heat generated by the first light-emitting elements 2a from being transferred to the second light-emitting elements 4a, the thermal properties of the entire light-emitting module 10a is improved.

In FIG. 2, the numbers and the positions of the first light-emitting elements 2a and the second light-emitting elements 4a are only an example, and any suitable arrangement is applicable.

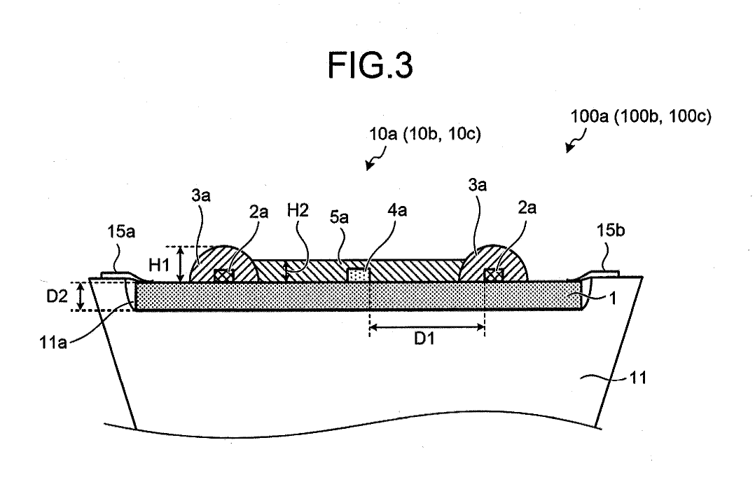

FIG. 3 illustrates a lateral cross-sectional view of the luminaire having the light-emitting module according to the first embodiment mounted thereon. FIG. 3 illustrates a cross-sectional view of the light-emitting module 10a taken along the line B-B in FIG. 2. In FIG. 3, illustration of the cover 13 of the luminaire 100a and a lower portion of the main body 11 is omitted. As illustrated in FIG. 3, the main body 11 of the luminaire 100a includes a depression 11a where the substrate 1 of the light-emitting module 10a is accommodated, and a fixing member 15a and a fixing member 15b for fixing the substrate 1. The light-emitting module 10a includes the substrate 1 being accommodated in the depression 11a of the main body 11.

The light-emitting module 10a is fixed to the main body 11 by an edge portion of the substrate 1 pressed downward of the depression 11a by pressing forces of the fixing member 15a and the fixing member 15b. Accordingly, the light-emitting module 10a is mounted on the luminaire 100a. A method of mounting the light-emitting module 10a to the luminaire 100a is not limited to the method shown in FIG. 3, and any suitable method such as adhering, fitting, screwing, and engaging may be employed.

As illustrated in FIG. 3, the distance D1 between the first light-emitting element 2a and the second light-emitting element 4a is longer than a thickness D2 of the substrate 1 in the perpendicular direction. The heat generated by light emission of the first light-emitting elements 2a and the second light-emitting elements 4a is liable to be transferred in the horizontal direction than in the perpendicular direction on the substrate 1. Therefore, for example, the heat generated by the first light-emitting elements 2a is transferred to the second light-emitting elements 4a via the horizontal direction of the substrate 1, and the light-emitting efficiency of the second light-emitting elements 4a is further deteriorated. However, by setting the distance D1 between the first light-emitting element 2a and the second light-emitting element 4a to be longer than the thickness D2 of the substrate 1 in the perpendicular direction, the heat generated by the first light-emitting elements 2a is inhibited from being transferred to the second light-emitting elements 4a via the horizontal direction of the substrate 1. Therefore, deterioration of the light-emitting efficiency of the second light-emitting elements 4a is inhibited. However, the distance D1 is not limited thereto, and may be any suitable value.

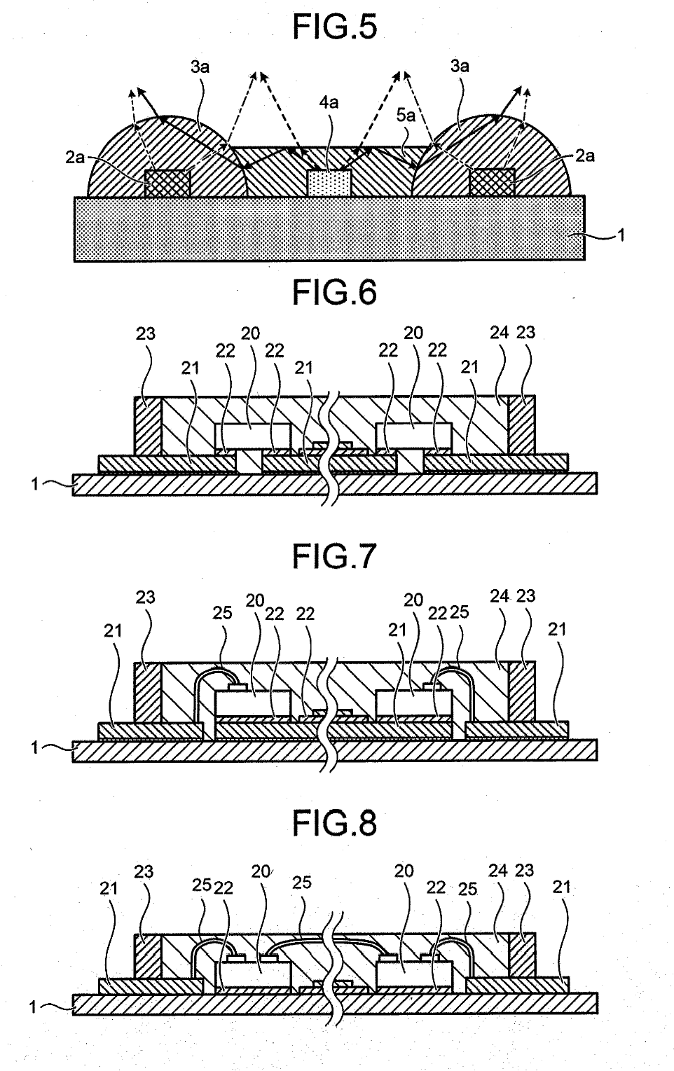

As illustrated in FIG. 3, a height H1 of the sealing member 3a is higher than a height H2 of the sealing member 5a. The effect described above will be described later with reference to FIG. 5. The height H1 of the sealing member 3a and the height H2 of the sealing member 5a may be the same.

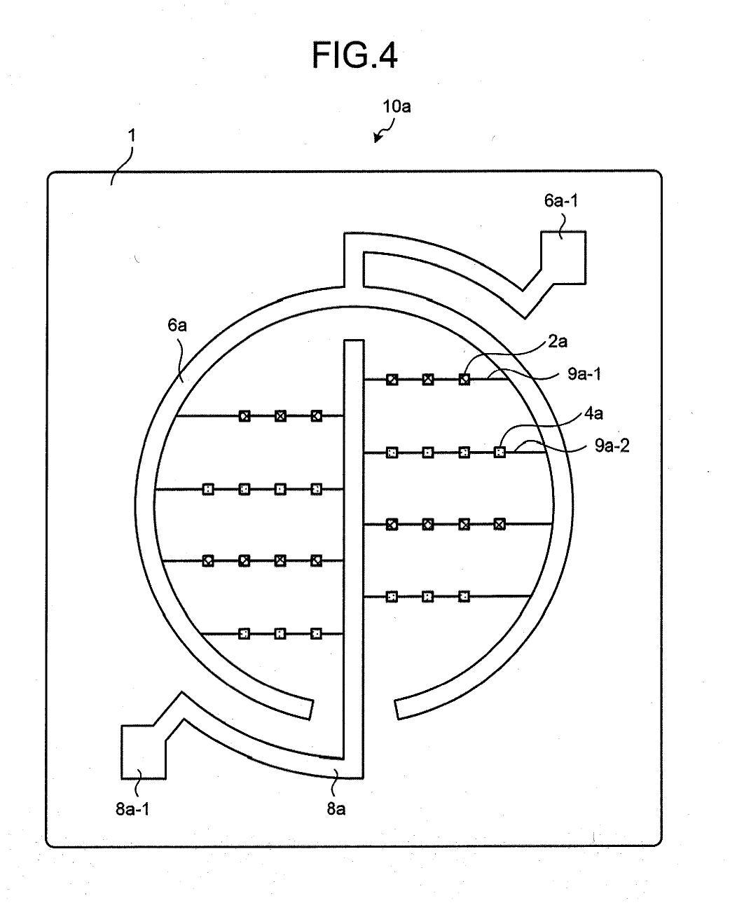

FIG. 4 illustrates electric wiring of the light-emitting module according to the first embodiment. In an example illustrated in FIG. 4, the light-emitting module 10a includes first light-emitting elements and second light-emitting elements which are elements connected to the first light-emitting elements in parallel and whose ratio of change in light-emitting efficiency and a ratio of change in voltage with respect to the change in temperature are larger than those of the first light-emitting elements. Specifically, the first light-emitting element group having a plurality of the first light-emitting elements connected in series and the second light-emitting element group having a plurality of the second light-emitting elements connected in series are connected in parallel. Also, there are the plurality of first light-emitting element groups and the plurality of second light-emitting element groups, and the plurality of the first light-emitting element groups and the second light-emitting element groups are connected in parallel. In the example illustrated in FIG. 4, the first light-emitting element groups and the second light-emitting element groups connected in parallel are connected to a common electricity supplying route.

In the following description, a case in which the first light-emitting element groups and the second light-emitting element groups are connected in parallel are described as an example. However, the connection is not limited thereto, and the first light-emitting element groups and the second light-emitting element groups may be connected in series, and the first light-emitting elements 2a and the second light-emitting elements 4a may be connected in series. In the example shown in FIG. 4, a case where there are the plurality of first light-emitting element groups and the plurality of second light-emitting element groups is exemplified. However, the numbers of the first light-emitting element groups and the second light-emitting element groups are not limited thereto, and one or both of the first light-emitting element groups and the second light-emitting element groups may include only one light-emitting element group.

In the example illustrated in FIG. 4, the light-emitting module 10a includes the electrode 6a-1 connected to the electrode bonding portion 14a-1 of the luminaire 100a and wiring 6a extending from the electrode 6a-1 on the substrate 1. Also, the light-emitting module 10a includes the electrode 8a-1 connected to the electrode bonding portion 14b-1 of the luminaire 100a and wiring 8a extending from the electrode 8a-1 on the substrate 1.

In the light-emitting module 10a, the plurality of first light-emitting elements 2a connected in series by bonding wires 9a-1 are connected to the wiring 6a and the wiring 8a on the substrate 1. In the light-emitting module 10a, the plurality of second light-emitting elements 4a connected in series by bonding wires 9a-2 are connected to the wiring 6a and the wiring 8a on the substrate 1. Consequently, the plurality of first light-emitting elements 2a connected in series by the bonding wires 9a-1 and the plurality of second light-emitting elements 4a connected in series by the bonding wires 9a-2 are connected in parallel.

FIG. 5 illustrates reflection of light-emitting colors of the respective light-emitting elements in the light-emitting module according to the first embodiment. As premise for FIG. 5, as described above, the index of refraction n1 of light of the sealing member 3a, the index of refraction n2 of light of the sealing member 5a, and the index of refraction n3 of light of gas enclosed in the space formed by the main body 11 and the cover 13 have the magnitude relationship of, for example, n3<n1<n2.

Then, as indicated by solid arrows in FIG. 5, light emitted from the second light-emitting elements 4a is substantially totally reflected by an interface between the sealing member 5a and the enclosed gas due to the magnitude relationship of refractive index described above and proceeds in the direction toward the sealing member 3a. As indicated by the solid arrows in FIG. 5, the light reflected by the interface between the sealing member 5a and the enclosed gas and proceeded toward the sealing member 3a is refracted by the interface between the sealing member 5a and the sealing member 3a and proceeds into the sealing member 3a due to the magnitude relationship of the refractive index described above.

In contrast, as shown by arrows of double dashed chain lines in FIG. 5 the light emitted from the first light-emitting elements 2a is refracted by the interface between the sealing member 3a and the enclosed gas due to the magnitude relationship of the index of refraction described above and proceeds in the direction toward the enclosed gas. Major part of the light emitted from the first light-emitting elements 2a is reflected by the interface between the sealing member 3a and the sealing member 5a due to the magnitude relationship of the index of refraction described above. The height H1 of the sealing member 3a is higher than the height H2 of the sealing member 5a. Therefore, the surface area of the interface between the sealing member 3a and the sealing member 5a may be decreased, while the surface area of the interface between the sealing member 3a and the enclosed gas may be increased.

In this manner, since major part of the light emitted from the first light-emitting elements 2a and the light emitted from the second light-emitting elements 4a are combined suitably in the vicinity of the interface between the sealing member 3a and the enclosed gas before going out, the uniformity of the light emission may be enhanced. Since the light-emitting module 10a takes out the light emitted from the second light-emitting elements 4a efficiently and is combined with the light emitted from the first light-emitting elements 2a efficiently, the number of second light-emitting elements 4a to be mounted may be reduced. Accordingly, the light-emitting module 10a inhibits worsening of the entire light-emitting property caused by the worsening of the light-emitting property of the second light-emitting elements 4a due to the heat.

Also, as indicated by arrows of broken lines in FIG. 5, part of the light emitted from the second light-emitting elements 4a is not reflected by an interface between the sealing member 5a and the enclosed gas and is refracted thereby and proceeds in the direction toward the enclosed gas above the sealing member 5a. In contrast, part of the light emitted from the first light-emitting elements 2a is refracted by the interface between the sealing member 3a and the enclosed gas and proceeds in the direction toward the enclosed gas above the sealing member 5a as indicated by arrows of chain lines in FIG. 5. In this manner, even though part of the light emitted from the second light-emitting elements 4a goes out upward from the sealing member 5a, since the sealing member 3a is located at a higher position than the sealing member 5a, the light of the first light-emitting elements 2a going out from an upper area of the sealing member 3a on the side of the sealing member 5a and the light of the second light-emitting elements 4a going out from the sealing member 5a are mixed further uniformly. Therefore, even though the LEDs emitting different colors are provided in different areas, color unevenness due to the color mixture is further inhibited.

The light-emitting module 10a achieves avoidance of the absorption of the light by phosphor and improvement of the light-emitting efficiency by sealing a second area in which the light-emitting amount is small, for example, where the second light-emitting elements 4a are arranged with a transparent resin which does not contain the phosphor. Also, the light-emitting module 10a achieves inhabitance of the color unevenness in LED module by sealing the second area where a predetermined number of the red LEDs are arranged with the transparent resin having a high diffusing property because the red light is diffused efficiently. In other words, the light-emitting module 10a is capable of reducing the lowering of color rendering properties and the light-emitting efficiency of the emitted light.

In the first embodiment described above, the first light-emitting elements 2a are arranged in a circular ring shape on the substrate 1, and the second light-emitting elements 4a are arranged in the vicinity of the center of the circular ring. However, the shape of arrangement of the first light-emitting elements 2a is not limited to the circular ring shape, and any suitable shape such as a rectangular shape or a diamond shape as long as it is formed into a ring shape.

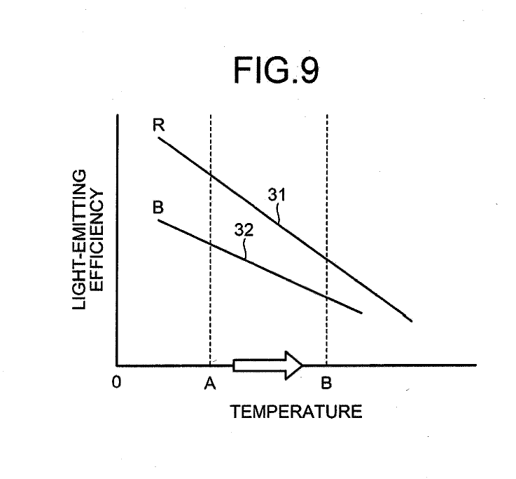

Referring now to FIG. 6 to FIG. 8, an example of the connecting structure of the light-emitting element in the first embodiment will be described. FIG. 6 illustrates an example of a structure of the light-emitting module showing a case where the light-emitting elements having two electrodes on the lower surface thereof are connected to a substrate. FIG. 7 illustrates an example of a structure of the light-emitting module showing a case where the light-emitting elements each having one electrode connected to another with a bonding wire on an upper surface thereof and one electrode on the lower surface thereof are connected to the substrate. FIG. 8 illustrates an example of a structure of the light-emitting module showing a case where the light-emitting elements each having two electrodes connected to others with bonding wires on an upper surface thereof are connected to the substrate.

In the example illustrated in FIG. 6 to FIG. 8, a wiring pattern 21 to be connected to an electrode of light-emitting elements 20 is formed on the upper surface of the substrate 1. The light-emitting elements 20 are first light-emitting elements 2a or second light-emitting elements 4a. The light-emitting element 20 and the substrate 1 or the wiring pattern 21 are connected by a connecting material and bonding wires 25. The connecting material includes, for example, die-bonding agent or solder. In the examples illustrated in FIG. 6 to FIG. 8, a reflecting frame 23 provided so as to surround a mounting area of the light-emitting element 20 and a sealing resin 24 configured to seal the light-emitting element 20 in the inside of the reflecting frame 23 are illustrated together for the sake of convenience of illustration.

Going back to the description of the connecting structure, the second connecting structure in which the second light-emitting elements 4a and the substrate 1 are connected is higher in thermal radiation in comparison with the first connecting structure in which the first light-emitting elements 2a and the substrate 1 are connected. In other words, the second light-emitting elements 4a is connected to the substrate 1 in a connecting structure having high thermal radiation in comparison with the first light-emitting elements 2a. Specifically, a thermal resistance between the second light-emitting elements 4a and the substrate 1 in the second connecting structure is set to be relatively lower than a thermal resistance between the first light-emitting elements 2a and the substrate 1 in the first connecting structure. Any suitable method may be employed such that, for example, making the thermal resistances different by changing the mounting modes of the first light-emitting elements 2a and the second light-emitting elements 4a, or making the thermal resistances different by equalizing the mounting modes of the first light-emitting elements 2a and the second light-emitting elements 4a and changing the die-bonding agent for connecting the light-emitting elements and the substrate.

In the example illustrated in FIG. 6, the light-emitting elements 20 each have two electrodes on a lower surface thereof such as a flip-chip type, and the electrodes and the wiring pattern are connected by soldering or a conductive paste. For example, silver paste corresponds to the conductive paste. In the example illustrated in FIG. 7, the light-emitting elements 20 each have one electrode on an upper surface thereof and one electrode on lower surface thereof, and the electrode on the upper surface is connected to another by a wire bonding, and the electrode on the lower surface and the wiring pattern are connected by soldering or the conductive paste. In the example illustrated in FIG. 8, the light-emitting elements 20 each have two electrodes on the upper surface thereof, the electrodes on the upper surface are connected to others by the wire bonding, and a lower portion of the light-emitting elements 20 are connected by a die-bonding agent such as a silicone agent.

As shown in FIG. 6 to FIG. 8, the light-emitting elements 20 are connected in different mounting modes, respectively. If the mounting modes are different, the thermal radiation of the light-emitting elements 20 also varies correspondingly. For example, if the light-emitting elements 20 are connected by the die-bonding agent such as the silicone agent, it is considered that the thermal radiation is lower than a case where the electrode and the wiring pattern are connected by soldering, or by the conductive paste. Consequently, it is considered that the connecting structures illustrated in FIG. 6 and FIG. 7 provide higher thermal radiation in comparison with the connecting structure illustrated in FIG. 8.

If the contact surface between the electrode and the wiring pattern is large, it is considered that the thermal radiation is higher than a case where the contact surface between the electrode and the wiring pattern is small. Here, in the example illustrated in FIG. 7, the lower surfaces of the light-emitting elements 20 are connected to the wiring pattern entirely. In the example illustrated in FIG. 6, as a result that two electrodes located on the lower surface are connected with the different wiring patterns respectively, the light-emitting elements 20 are not connected to the wiring patterns over the entire surfaces thereof. As a result, the thermal radiation is higher in the connecting structure illustrated in FIG. 7 when comparing the connecting structure illustrated in FIG. 6 and the connecting structure illustrated in FIG. 7.

In light of characteristics of the connecting structures described above, for example, a connecting structure in which the first light-emitting elements 2a each having two electrodes which are connected to others by the bonding wires on the upper surface thereof are connected to the substrate 1 as illustrated in FIG. 8 is employed in the light-emitting module 10a as the first connecting structure. In this case, for example, a connecting structure in which the second light-emitting elements 4a each having at least one electrode on the lower surface thereof are connected to the substrate 1 as illustrated in FIG. 6 and FIG. 7 is employed in the light-emitting module 10a, as the second connecting structure.

However, the connecting structure is not limited thereto, and a connecting structure in which the first light-emitting elements 2a each having two electrodes on the lower surface thereof is connected to the substrate 1 as illustrated in FIG. 6 may be employed in the light-emitting module 10a as the first connecting structure. In this case, for example, a connecting structure in which the second light-emitting elements 4a each having one electrode on the lower surface thereof are connected to the substrate 1 as illustrated in FIG. 7 is employed in the light-emitting module 10a as the second connecting structure.

For example, by employing the same mounting method for mounting the LED elements and choosing the die-bonding agent having different thermal resistances to be used in the first connecting structure and the second connecting structure, the thermal radiations of the first connecting structure and the second connecting structure may be differentiated. For example, in the first connecting structure and the second connecting structure, connection may be achieved by connecting the first light-emitting elements 2a and the second light-emitting elements 4a each having two electrodes to be connected to others on the upper surface thereof to the substrate 1 by the bonding wires, then connecting by using a first die-bonding agent in the first connecting structure, and connecting by using a second die-bonding agent having a higher thermal radiation than the first die-bonding agent in the second connecting structure. For example, a silicone agent is used as the first die-bonding agent and silver paste or eutectic metal solder are used as the second die-bonding agent. In this case, the thermal resistance of the silver paste or the eutectic metal solder is lower than the silicone agent and the thermal radiation of the second connecting structure is lower than that of the first connecting structure. The first die-bonding agent and the second die-bonding agent may be selected from any suitable die-bonding agent on the basis of the difference in thermal radiation. However, when connecting the electrode and the wiring, the conductive die-bonding agent is used.

In the above-described description, a case in which the thermal radiation in the case in which the LED elements each having one electrode on the lower surface thereof as illustrated in FIG. 7 are connected is larger than the thermal radiation in the case where the LED elements each having two electrodes on the lower surface thereof as illustrated in FIG. 6 are connected is shown as an example. However, the relationship of the thermal radiation is not limited thereto. In other words, it is considered that the thermal radiation of the connecting structure illustrated in FIG. 7 becomes smaller than the thermal radiation of the connecting structure illustrated in FIG. 6 by changing the contact surface between the wiring pattern and the electrode, the contact surface in which the light-emitting elements and the substrate are brought into contact by the conductive paste, the solder, or the like. In such a case, the connecting structure illustrated in FIG. 7 may be used as the first connecting structure and the connecting structure illustrated in FIG. 6 may be used as the second connecting structure.

The light-emitting module according to the first embodiment includes the substrate 1 and the first light-emitting elements 2a connected to the substrate 1. The light-emitting module includes the second light-emitting elements 4a being larger in ratio of change of the light-emitting efficiency with respect to the change in temperature than that of the first light-emitting elements 2a and connected to the substrate in the second connecting structure in which the thermal radiation is higher than the first connecting structure in which the first light-emitting elements 2a and the substrate 1 are connected. Consequently, the change in balance of light output from the plurality of types of the light-emitting elements may be inhibited.

FIG. 9 illustrates an example of the relationship between the temperature and the light-emitting efficiency of the light-emitting element. Reference sign R31 in FIG. 9 shows a value of the red LED and reference sign B32 in FIG. 6 shows a value of the blue LEDs. As illustrated in FIG. 9, the red LEDs have the ratio of change of the light-emitting efficiency with respect to the change in temperature larger than that of the blue LED.

In other words, according to the first embodiment, the second light-emitting elements 4a having the ratio of change of the light-emitting efficiency with respect to the change in temperature larger than that of the first light-emitting elements 2a is connected to the substrate 1 in the connecting structure having higher heat radiation than that of the first light-emitting elements 2a. Consequently, the change in temperature of the second light-emitting elements 4a becomes smaller than that of the first light-emitting elements 2a and, consequently, the change in balance of light output from the plurality of types of the light-emitting elements may be inhibited. In other words, in comparison with a case in which the temperature of the first light-emitting elements 2a and the temperature of the second light-emitting elements 4a change in the same manner, the change in balance of light output from the plurality of types of the light-emitting element's may be inhibited.

In the light-emitting module according to the embodiments, the thermal resistance between the second light-emitting element and the substrate in the second connecting structure is relatively lower than the thermal resistance between the first light-emitting element and the substrate in the first connecting structure. Consequently, the change in balance of light output from the plurality of types of the light-emitting elements may be inhibited.

In the light-emitting module according to the embodiments, the light-emitting efficiencies of the first light-emitting element and the second light-emitting element decrease with increase in temperature, and increase with decrease in temperature. Consequently, the change in balance Of light output from the plurality of types of the light-emitting elements may be inhibited.

In the light-emitting module according to the embodiments, for example, the first light-emitting elements are blue LED (Light Emitting Diode) elements and the second light-emitting elements are red LED elements. Consequently, the change in balance of light output from the plurality of types of the light-emitting elements may be inhibited by the blue LED elements and the red LED elements.

In the light-emitting module according to the embodiments, for example, the light-emitting element and the substrate are connected with the first die-bonding agent in the first connecting structure. Also, for example, in the second connecting structure, the light-emitting element and the substrate are connected with the second die-bonding agent having a lower thermal resistance than that of the first die-bonding agent. In the light-emitting module, for example, connection is performed using the silicone agent in the first connecting structure, and using the silver paste in the second connecting structure. Consequently, by changing the die-bonding agent by types of the LED elements, the change in balance of light output from the plurality of types of the light-emitting elements may be inhibited easily.

In the light-emitting module according to the embodiments, for example, the first light-emitting element and the second light-emitting element each have two electrodes to be connected to others by the bonding wires on the upper surfaces thereof. In the light-emitting module, for example, in the first connecting structure, the first light-emitting element and the substrate are connected with the silicone agent and, in the second connecting structure, the second light-emitting element and the substrate are connected with the silver paste. Consequently, by changing the die-bonding agent by types of the LED elements, the change in balance of light output from the plurality of types of the light-emitting elements may be inhibited.

In the light-emitting module according to the embodiments, for example, the substrate has the wiring pattern on the surface thereof. The first light-emitting element includes two electrodes to be connected to others by the bonding wires on the upper surfaces thereof. The second light-emitting element includes at least one electrode on a lower surface thereof. For example, in the first connecting structure, the first light-emitting element and the substrate are connected with the silicone agent. For example, in the second connecting structure, the electrode provided on the lower surface of the second light-emitting element and the wiring pattern of the substrate are connected. Consequently, by changing mounting mode of the light-emitting elements, the change in balance of light output from the plurality of types of the light-emitting elements may be easily inhibited.

### Second Embodiment

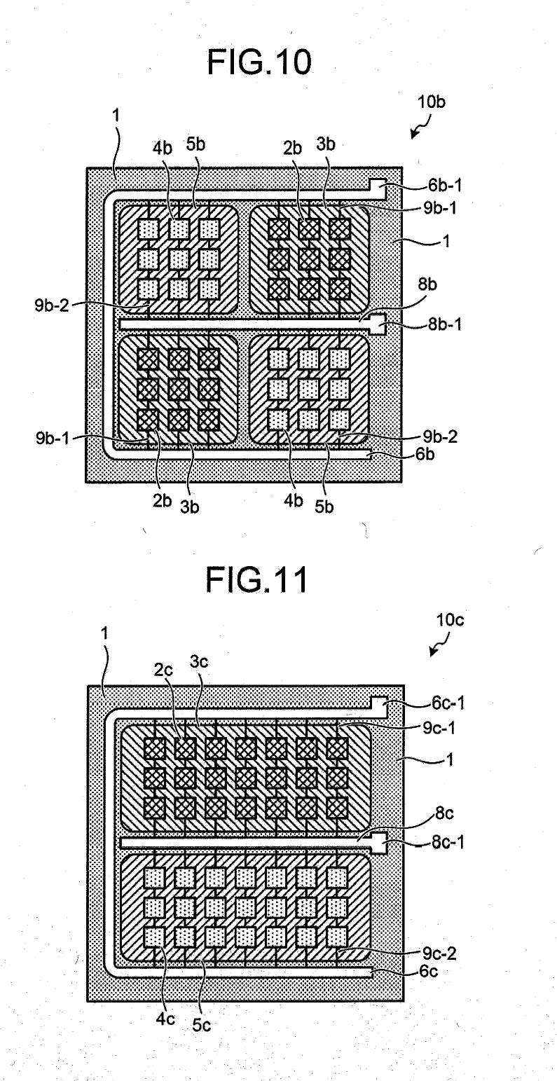

A second embodiment is different from the first embodiment in mode of arrangement of the LEDs. Other points are the same as the first embodiment, and hence the description will be omitted. FIG. 10 illustrates a top view of the light-emitting module according to the second embodiment. FIG. 10 illustrates a top view of the light-emitting module 10b according to the second embodiment viewed from the direction indicated by the arrow A in FIG. 1.

As illustrated in FIG. 10, the light-emitting module 10b includes two first light-emitting element groups including a plurality of first light-emitting elements 2b arranged on a diagonal line on the substrate 1. Also, the light-emitting module 10b includes two second light-emitting element groups including a plurality of second light-emitting elements 4b arranged on a diagonal line which is symmetry with the arrangement of the first light-emitting element groups with respect to the center of the substrate 1 on the substrate 1.

Also, the light-emitting module 10b includes an electrode 6b-1 connected to the electrode bonding portion 14a-1 of a luminaire 100b and wiring 6b extending from the electrode 6b-1 on the substrate 1. Also, the light-emitting module 10b includes wiring 8b connected in parallel with the wiring 6b via the first light-emitting elements 2b connected in series by bonding wires 9b-1 and the second light-emitting elements 4b connected in series by bonding wires 9b-2 on the substrate 1. The wiring 8b includes an electrode 8b-1 to be connected to the electric bonding portion 14b-1 of the luminaire 100b at a distal end of extension. The first light-emitting elements 2b have the same thermal properties as the first light-emitting element 2a in the first embodiment. The second light-emitting elements 4b have the same thermal properties as the second light-emitting elements 4a in the first embodiment.

As illustrated in FIG. 10, if the first light-emitting elements 2b and the second light-emitting elements 4b are arranged on the substrate 1, first areas sealed with a sealing member 3b and second areas sealed with a sealing member 5b are located at a point symmetry with respect to the center of the substrate 1. Therefore, the light-emitting module 10b combines light emitted from the first light-emitting elements 2b and light emitted from the second light-emitting elements 4b in a balanced manner, so that the light having a desired light-emitting pattern, brightness, and tone can be obtained easily.

### Third Embodiment

A third embodiment is different from the first embodiment and the second embodiment in mode of arrangement of LEDs. Other points are the same as the first embodiment and the second embodiment, and hence the description will be omitted. FIG. 11 is a top view showing the light-emitting module according to a third embodiment. FIG. 11 illustrates a top view of the light-emitting module 10c according to the third embodiment viewed from the direction indicated by the arrow A in FIG. 1.

As illustrated in FIG. 11, the light-emitting module 10c includes the first light-emitting element group including a plurality of first light-emitting elements 2c arranged in one of areas divided into two halves on the substrate 1. The light-emitting module 10c includes the second light-emitting element group including a plurality of second light-emitting elements 4c arranged in the other one of areas divided into two halves where the first light-emitting element group is not arranged on the substrate 1.

The light-emitting module 10c includes an electrode 6c-1 connected to the electrode bonding portion 14a-1 of a luminaire 100c and wiring 6c extending from the electrode 6c-1. Also, the light-emitting module 10c includes wiring 8c connected in parallel with the wiring 6c via the plurality of first light-emitting elements 2c connected in series by bonding wires 9c-1 and the plurality of second light-emitting elements 4c connected in series by bonding wires 9c-2 on the substrate 1. The wiring 8c includes an electrode 8c-1 to be connected to the electric bonding portion 14b-1 of the luminaire 100c at a distal end of extension. The first light-emitting elements 2c have the same thermal properties as the first light-emitting element 2a in the first embodiment. The second light-emitting elements 4c have the same thermal properties as the second light-emitting elements 4a of the first embodiment.

As illustrated in FIG. 11, when the first light-emitting elements 2c and the second light-emitting elements 4c are put together on the substrate 1, a first area sealed with a sealing member 3c and a second area sealed with a sealing member 5c are formed separately. Therefore, the control unit 14 of the light-emitting module 100c can perform driving control and thermal management of the first light-emitting elements 2c and the second light-emitting elements 4c easily. Furthermore, the light-emitting module 10c inhibits worsening of the entire light-emitting property due to the worsening of the light-emitting property of the second light-emitting elements 4c due to the heat.

### Other Embodiments

For example, in the embodiments described above, the first light-emitting elements 2a to 2c are defined as the first light-emitting elements, and the second light-emitting elements 4a to 4c are defined as the second light-emitting elements. However, the light-emitting elements are not limited thereto, and any suitable light-emitting elements are applicable irrespective of emitted color as long as it is a combination of the first light-emitting elements and the second light-emitting elements which is inferior in thermal performance in comparison with the first light-emitting element. Also, in the embodiments described above, the materials of the sealing members 3a to 3c and the sealing members 5a to 5c are different, and the indices of light refraction of the respective materials are different. However, the material of the sealing member is not limited thereto, and the sealing members 3a to 3c and the sealing members 5a to 5c may be formed of the same material. The method of sealing the first light-emitting elements 2a to 2c and the second light-emitting elements 4a to 4c with the sealing members 3a to 3c ad the sealing members 5a to 5c are not limited to those described in the embodiments, and various suitable methods may be used.

Although several embodiments of the invention have been described, the embodiments are shown as examples and are not intended to limit the scope of the invention. These embodiments may be implemented in other various modes, and various omissions, replacements, and modifications may be made without departing the scope of the invention. These embodiments and the modifications are also included in the scope and gist of the invention.

What is claimed is:

1. A light-emitting module comprising:
a substrate;
a first light-emitting element mounted on the substrate through a first connecting structure; and
a second light-emitting element having a light-emitting efficiency that is more sensitive to a change in temperature than that of the first light-emitting element, and mounted on the substrate through a second connecting structure having a higher thermal radiation than the first connecting structure.

2. The light-emitting module according to claim 1, wherein a thermal resistance between the second light-emitting element and the substrate is lower than a thermal resistance between the first light-emitting element and the substrate.

3. The light-emitting module according to claim 1, wherein the light-emitting efficiencies of the first light-emitting element and the second light-emitting element decrease in response to an increase in temperature, and increase in response to a decrease in temperature.

4. The light-emitting module according to claim 1, wherein
the first light-emitting element is a blue LED (Light Emitting Diode) element, and
the second light-emitting element is a red LED element.

5. The light-emitting module according to claim 1, wherein
the light-emitting element and the substrate are connected through a first die-bonding agent, and
the light-emitting element and the substrate are connected through a second die-bonding agent having a lower thermal resistance than the first die-bonding agent.

6. The light-emitting module according to claim 1, wherein
the first light-emitting element and the second light-emitting element each include two electrodes on an upper surface thereof,
the first light-emitting element and the substrate are connected through a silicone agent, and
the second light-emitting element and the substrate are connected through a silver paste.

7. The light-emitting module according to claim 1, wherein
the substrate includes a wiring pattern on a surface thereof,
the first light-emitting element includes two electrodes on an upper surface thereof,
the second light-emitting element includes at least one electrode on a lower surface thereof,
the first light-emitting element and the substrate are connected through a silicone agent, and
the electrode of the second light-emitting element and the wiring pattern of the substrate are in direct contact with each other.

8. A luminaire comprising:
a light-emitting module including a substrate, a first light-emitting element mounted on the substrate through a first connecting structure, and a second light-emitting element having a light-emitting efficiency that is more sensitive to a change in temperature than that of the first light-emitting element, and mounted on the substrate through a second connecting structure having a higher thermal radiation than the first connecting structure; and
a main body having the light-emitting module disposed thereon.

9. The luminaire according to claim 8, wherein a thermal resistance between the second light-emitting element and the substrate is lower than a thermal resistance between the first light-emitting element and the substrate.

10. The luminaire according to claim 8, wherein the light-emitting efficiencies of the first light-emitting element and the second light-emitting element decrease in response to an increase in temperature, and increase in response to a decrease in temperature.

11. The luminaire according to claim 8, wherein
the first light-emitting element is a blue LED (Light Emitting Diode) element, and
the second light-emitting element is a red LED element.

12. The luminaire according to claim 8, wherein
the light-emitting element and the substrate are connected through a first die bonding agent, and
the light-emitting element and the substrate are connected through a second die-bonding agent having a lower thermal resistance than the first die-bonding agent.

13. The luminaire according to claim 8, wherein
the first light-emitting element and the second light-emitting element each include two electrodes on an upper surface thereof,
the first light-emitting element and the substrate are connected through a silicone agent, and
the second light-emitting element and the substrate are connected through a silver paste.

14. The luminaire according to claim 8, wherein
the substrate includes a wiring pattern on a surface thereof,
the first light-emitting element includes two electrodes on an upper surface thereof,
the second light-emitting element includes at least one electrode on a lower surface thereof,
the first light-emitting element and the substrate are connected through a silicone agent, and
the electrode of the second light-emitting element and the wiring pattern of the substrate are in direct contact with each other.

15. A light-emitting module comprising:
a substrate;
a first light emitting diode (LED) mounted on the substrate; and
a second LED mounted on the substrate,
wherein a thermal resistance between the first LED and the substrate is higher than a thermal resistance between the second LED and the substrate.

16. The light-emitting module according to claim 15, wherein light-emitting efficiencies of the first and second LEDs decrease in response to an increase in temperature, and increase in response to a decrease in temperature.

17. The light-emitting module according to claim 16, wherein the light-emitting efficiency of the first LED changes in response to a change in temperature at a slower rate than the light-emitting efficiency of the second LED.

18. The light-emitting module according to claim 15, wherein
the first LED is a blue LED, and
the second LED is a red LED.

19. The light-emitting module according to claim 15, wherein
the first LED and the substrate are connected through a first die-bonding agent, and
the second LED and the substrate are connected through a second die-bonding agent having a lower thermal resistance than the first die-bonding agent.

20. The light-emitting module according to claim 19, wherein the first die-bonding agent is a silicone agent, and the second die-bonding agent is a silver paste.
